(19) United States
(12) Patent Application Publication
(10) Pub. No.: US 2008/0199975 A1
(43) Pub. Date: Aug. 21, 2008

(54) METHODS OF FORMING A METAL OXIDE LAYER PATTERN HAVING A DECREASED LINE WIDTH OF A PORTION THEREOF AND METHODS OF MANUFACTURING A SEMICONDUCTOR DEVICE USING THE SAME

(75) Inventors: Min-Joon Park, Seoul (KR); Chang-Jin Kang, Gyeonggi-do (KR); Dong-Hyun Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/032,018

(22) Filed: Feb. 15, 2008

(30) Foreign Application Priority Data
Feb. 15, 2007 (KR) 2007-0015742

(51) Int. Cl. H01L 21/18; H01L 21/3065

(52) U.S. Cl. 438/3; 438/722; 257/E21.18; 257/E21.218

(57) ABSTRACT

Provided herein are methods of forming a metal oxide layer pattern on a substrate including providing a preliminary metal oxide layer on a substrate; etching the preliminary metal oxide layer to provide a preliminary metal oxide layer pattern, wherein the line width of the preliminary metal oxide layer pattern gradually increases in a vertically downward direction; and etching the preliminary metal oxide layer pattern to form a metal oxide layer pattern in a manner so as to decrease the line width of a lower portion of the preliminary metal oxide layer. The present invention also provides methods of manufacturing a semiconductor device including forming a metal oxide layer and a first conductive layer on a substrate; etching the metal oxide layer to provide a preliminary metal oxide layer pattern, wherein the line width of the preliminary metal oxide layer pattern gradually increase in a vertically downward direction; etching the first conductive layer to provide a first conductive layer pattern; and etching the preliminary metal oxide layer pattern to provide a metal oxide layer pattern in a manner so as to decrease the line width of a lower portion of the preliminary metal oxide layer pattern.

### CROSS-REFERENCE TO RELATED APPLICATIONS

This patent application claims priority to Korean Patent Application No. 2007-15742, filed Feb. 15, 2007, the disclosure of which is hereby incorporated by reference in its entirety.

### FIELD OF THE INVENTION

Embodiments of the present invention relate to methods of forming a metal oxide layer pattern on a substrate and methods of manufacturing a semiconductor device using the methods of forming the metal oxide layer pattern described herein.

### BACKGROUND OF THE INVENTION

Semiconductor memory devices may include volatile memory devices and non-volatile memory devices. Generally, the volatile memory devices may include dynamic random access memory (DRAM) devices and static random access memory (SRAM) devices. The non-volatile memory devices may include erasable programmable read-only memory (EPROM) devices, electrically erasable programmable read-only memory (EEPROM) devices and flash memory devices. When power is turned off, the volatile memory devices may lose stored data, but the volatile memory devices may maintain stored data.

The flash memory devices may be further classified into floating gate-type memory devices and floating trap-type memory devices. A floating gate-type memory device stores and erases data by storing free charges in or removing free charges from a floating gate. A floating trap-type memory device stores or erases data by storing electrons or holes in a charge-trapping layer. During the manufacture of a floating trap-type memory device, a tunnel insulation layer, a charge-trapping layer, a blocking layer and a conductive layer are sequentially stacked on a substrate and they are formed to their respective patterns.

In order to improve the degree of integration of floating trap-type memory devices, materials with a high dielectric constant are chosen to form the blocking layer pattern. Materials with a high dielectric constant may include aluminum oxide (Al₂O₃), hafnium oxide (HfO₂), zirconium oxide (ZrO₂), tantalum oxide (TaO₂), hafnium aluminate (HfAlO), zirconium silicate (ZrSiO), hafnium silicate (HfSiO), lanthanum aluminate (LaAlO), and/or a combination thereof.

In a floating trap-type memory device, the line width of the lower portion of a pattern may be longer than that of the upper portion due to a regular patterning process. Specifically, the line width of a blocking layer pattern may be longer than that of a conductive layer pattern. The conductive layer pattern is on the blocking layer pattern. Consequently, the spaces between adjacent transistors may become smaller while the degree of integration of floating trap-type memory devices increases.

When a conductive layer and a blocking layer are partially etched to form the conductive layer pattern and the blocking layer pattern, the residue from etching the conductive layer may stay on the sidewall of the blocking layer pattern and the upper face of the substrate. The etch residue may have an adverse impact on the reliability of the floating gate-type memory device at least because of possible conductivity of the etch residue.

New types of non-volatile memory devices have been developed, for example, memory devices made from ferroelectric material. The ferroelectric material used herein refers to a nonlinear dielectric material and its dielectric polarization has a hysteresis loop when an electric field is applied thereto. For example, the ferroelectric material used herein may include lead zirconate titanate (Pb(Zr, Ti)O₃; PZT), strontium bismuth titanate (SrBi₂Ti₂O₉; SBT), barium strontium titanate (Ba(Sr, Ti)O₃; BST), and/or a combination thereof. A ferroelectric random access memory (FRAM) device uses a stable polarized state of a ferroelectric material. In the FRAM device, the dielectric layer of a DRAM device is replaced with a ferroelectric layer, and as a result, data stored in the FRAM device may be maintained even when power is turned off. In addition, the FRAM device may have advantages of operating at a high speed, at a low voltage and/or high durability. In view of these advantages, FRAM devices may become the next-generation non-volatile semiconductor memory devices.

A FRAM device may include a transistor and a capacitor. The capacitor may be formed by patterning an upper conductive layer, a ferroelectric layer and a lower conductive layer, after these layers are sequentially stacked. During the process of partially etching the upper conductive layer and the ferroelectric layer, etch residue from the upper conductive layer may remain on the sidewall of the ferroelectric layer pattern. Thus, at least because of the possible conductivity of the residue, currents may flow through the ferroelectric layer pattern as a dielectric layer, which decreases the reliability of the FRAM device.

### SUMMARY OF THE INVENTION

According to some embodiments of the present invention, methods of forming a metal oxide layer pattern on a substrate include providing a metal oxide layer on a substrate; etching the metal oxide layer to provide a preliminary metal oxide layer pattern, wherein the line width of the preliminary metal oxide layer pattern gradually increases in a vertically downward direction; and etching the preliminary metal oxide layer pattern to form a metal oxide layer pattern in a manner so as to decrease the line width of a lower portion of the preliminary metal oxide layer pattern.

In some embodiments, the step of etching the metal oxide layer to provide the preliminary metal oxide layer pattern is performed by using a plasma etching process with a source gas. In some embodiments, the source gas includes a halogen-containing gas, an inert gas and/or a combination thereof.

In some embodiments, the metal oxide layer includes a material with a high dielectric constant and/or a ferroelectric material.

In some embodiments, the plasma etching process is performed at a temperature of about 0° C. to about 300° C., under a pressure of about 1 to about 100 mTorr, and at a bias power level of about 0 to about 500 W.

According to another embodiment of the present invention, methods of manufacturing a semiconductor device include forming a metal oxide layer and a first conductive layer on a substrate; etching the metal oxide layer to provide a preliminary metal oxide layer pattern, wherein the line width of the preliminary metal oxide layer pattern gradually increase in a vertically downward direction; etching the first conductive layer to provide a first conductive layer pattern; and etching the preliminary metal oxide layer pattern to provide a metal oxide layer pattern in a manner so as to decrease the line width of a lower portion of the preliminary metal oxide layer pattern.

In some embodiments, the methods of manufacturing a semiconductor device further include forming a tunnel insulation layer pattern and a charge-trapping layer pattern on the substrate prior to forming the metal oxide layer.

In some embodiments, etching the preliminary metal oxide layer pattern is performed by using a plasma etching process with a source gas comprising a halogen-containing gas, an inert gas and/or a combination thereof, and the amount of the halogen-containing gas being in a range from about 0.1 to about 10% by weight based on the total weight of the source gas.

According to another embodiment, the metal oxide layer may be used as a blocking layer pattern. In particular embodiments, the metal oxide layer pattern may serve as a dielectric layer.

### BRIEF DESCRIPTION OF THE DRAWINGS

The above and other aspects of the present invention will become readily apparent by reference to the following detailed description when considering such in conjunction with the accompanying drawings, in which:

FIGS. 1 through 3 present cross-sectional views illustrating a method of forming a metal oxide layer pattern according to some embodiments of the present invention.

FIGS. 4 through 9 present cross-sectional views illustrating a method of forming a non-volatile memory device using the method of forming a metal oxide layer according to FIGS. 1 to 3.

FIGS. 10 through 20 present cross-sectional views illustrating a method of forming a ferroelectric memory device using a method of forming a metal oxide layer according to FIGS. 1 to 3.

The present invention will now be described more fully hereinafter with reference to the accompanying drawings, in which embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

### DETAILED DESCRIPTION

The terminology used herein is for the purpose of describing particular embodiments only and is not intended to be limiting of the present invention. As used in the description of the embodiments of the invention and the appended claims, the singular forms “a, “an” and “the” are intended to include the plural forms as well, unless the context clearly indicates otherwise. Also, as used herein, “and/or” refers to and encompasses any and all possible combinations of one or more of the associated listed items.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element, a substrate or layer is referred to as being “on,” “connected to” or “coupled to” another element, substrate or layer, it can be directly on, connected or coupled to the other element or layer or intervening elements or layers may be present. In contrast, when an element, a layer or substrate is referred to as being “directly on,” “directly connected to” or “directly coupled to” or introduced, exposed or feed “directly onto” another element or layer, no intervening elements or layers present. As used herein, the term “and/or” includes any and all in a mixture of one or more of the associated listed items.

Moreover, it will be understood that steps comprising the methods provided herein can be performed independently or at least two steps can be combined. Additionally, steps comprising the methods provided herein, when performed independently or combined, can be performed at the same temperature and/or atmospheric pressure or at different temperatures and/or atmospheric pressures without departing from the teachings of the present invention.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

According to some embodiments of the present invention, methods of forming a metal oxide layer pattern on a substrate, include providing a metal oxide layer on a substrate; etching the metal oxide layer to provide a preliminary metal oxide layer pattern, wherein the line width of the preliminary metal oxide layer pattern gradually increases in a vertically downward direction; etching the preliminary metal oxide layer pattern to form a metal oxide layer pattern in a manner so as to decrease the line width of a lower portion of the preliminary metal oxide layer pattern. In some embodiments, etching the preliminary metal oxide layer pattern is performed at a temperature in a range of about 0° C. to about 300° C., under a pressure in a range of about 1 to about 100 mTorr, and at a bias power level in a range of about 0 to about 500 W.

According to another embodiment, methods manufacturing a semiconductor device include forming a metal oxide layer and a first conductive layer on a substrate; etching the metal oxide layer to provide a preliminary metal oxide layer pattern, wherein the line width of the preliminary metal oxide layer pattern gradually increases in a vertically downward direction; etching the first conductive layer to provide a first conductive layer pattern; and etching the preliminary metal oxide layer pattern to provide a metal oxide layer pattern in a manner so as to decrease the line width of a lower portion of the preliminary metal oxide layer pattern.

In some embodiments, the method of manufacturing a semiconductor device further includes forming a tunnel insulation layer pattern and a charge-trapping layer pattern on the substrate prior to forming the metal oxide layer. In another embodiment, the first conductive layer includes polysilicon doped with impurities, a metal, a metal silicide, a metal nitride, and/or a combination thereof. In some embodiments, the metal oxide layer includes PZT (Pb(Zr, Ti )O₃), SBT (SrBi₂Ti₂O₉), BST(Ba(Sr, Ti)O₃), and/or a combination thereof. Yet, in some embodiments, the methods of manufacturing a semiconductor device further include forming a second conductive layer prior to etching the metal oxide layer to provide a preliminary metal oxide layer pattern. In some embodiments, the second conductive layer includes platinum (Pt), iridium (Ir), palladium (Pd), ruthenium (Ru) and/or a combination thereof. In some embodiments, the metal oxide layer pattern serves as a blocking layer pattern or a dielectric pattern. In some embodiments, etching the preliminary metal oxide layer pattern is performed by using a plasma etching process with a source gas including a halogen-containing gas, an inert gas and/or a combination thereof, and the amount of the halogen-containing gas being in a range from about 0.1 to about 10% by weight based on the total weight of the source gas.

In some embodiments, etching the metal oxide layer to provide a preliminary metal oxide layer pattern, etching the first conductive layer to provide a first conductive layer pattern and etching the preliminary metal oxide layer pattern to provide a metal oxide layer pattern are performed in-situ.

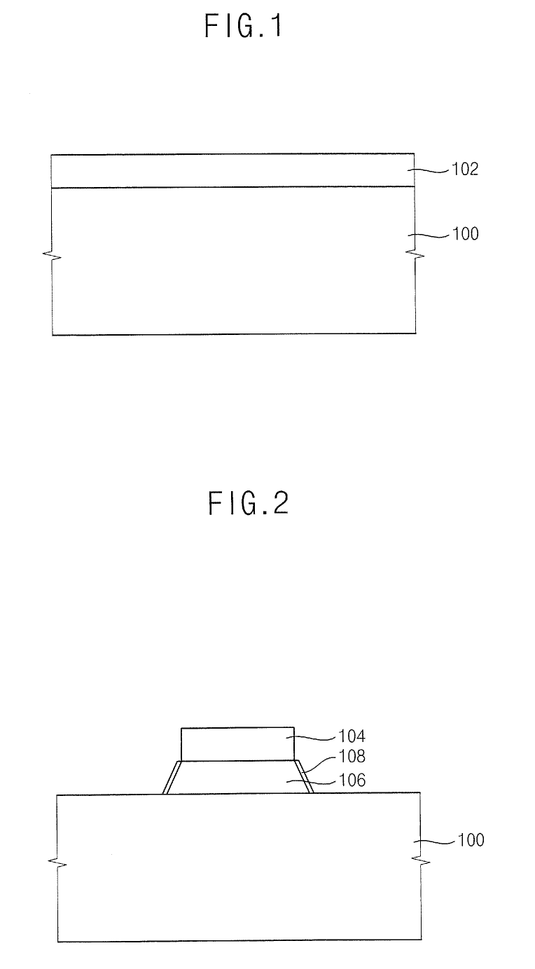

FIGS. 1 through 3 present cross-sectional views illustrating a method of forming a metal oxide layer pattern in accordance with some embodiments of the present invention.

Referring to FIG. 1, a metal oxide layer 102 may be formed on a substrate 100. The substrate 100 may be a semiconductor substrate such as a silicon substrate or a germanium substrate, for example, a silicon-on-insulator (SOI) substrate or a germanium-on-insulator (GOI) substrate. According to some embodiments of the present invention, the metal oxide layer 102 may include one or more materials with a high dielectric constant or one or more ferroelectric materials. Material having a high dielectric constant may include aluminum oxide (Al₂O₃), hafnium oxide (HfO₂), zirconium oxide (ZrO₂), tantalum oxide (TaO₂), hafnium aluminate (HfAlO), zirconium silicate (ZrSiO), hafnium silicate (HfSiO), lanthanum aluminate (LaAlO), and/or a combination thereof. The metal oxide layer 102 including the material with the high dielectric constant may be formed using a chemical vapor deposition (CVD) process and/or an atomic layer deposition (ALD) process. The ferroelectric material may include lead zirconate titanate (Pb(Zr, Ti)O₃; PZT), strontium bismuth titanate (SrBi₂Ti₂O₉; SBT), barium strontium titanate (Ba(Sr, Ti)O₃; BST), and/or a combination thereof. The metal oxide layer 102 including the ferroelectric material may be formed using a metal-organic chemical vapor deposition (MOCVD) process, a sol-gel process and/or an ALD process.

Referring to FIG. 2, a mask pattern 104 may be formed on the metal oxide layer 102 to at least partially expose the metal oxide layer 102. According to some embodiments, the mask pattern 104 may be formed using a nitride. Suitable nitrides may include silicon nitride, silicon oxynitride, and/or a combination thereof.

The metal oxide layer 102 may be partially etched to form a preliminary metal oxide layer pattern 106 using the mask pattern 104 as an etching mask. In some embodiments, the metal oxide layer 102 may be partially etched by using an anisotropic dry etching process, for example, a plasma etching process.

In some embodiments, the substrate 100 with the metal oxide layer 102 and the mask pattern 104 may be etched in a chamber. A first source gas of the etching process including a halogen-containing gas and/or an inert gas may be introduced into the chamber. The halogen-containing gas may include carbon tetrafluoride (CF₄), hydrogen bromide (HBr), chlorine (Cl₂), and/or a combination thereof. In some embodiments, the halogen-containing gas has an amount of at least about 10% by weight based on the total weight of the first source gas. The inert gas may include nitrogen (N₂) gas, helium (He) gas, neon (Ne) gas, argon (Ar) gas, and/or a combination thereof. The plasma etching process may be performed under substantially the same conditions as those of a regular process of etching a metal oxide layer.

In FIG. 2, the line width of the lower portion of a preliminary metal oxide layer pattern 106 may be longer than that of the upper portion at least due to the characteristics of the etching process. In some embodiments, the line width of the preliminary metal oxide layer pattern 106 may gradually increase in a vertically downward direction from the upper face of the metal oxide layer. When the line width of the lower portion of the preliminary metal oxide layer pattern 106 is longer, the overlapping area of the preliminary metal oxide layer pattern 106 and the substrate 100 may increase, which may have an adverse impact on the degree of integration of a memory device. In addition, etch residue from the metal oxide layer 102 may remain on the sidewall of the preliminary metal oxide layer pattern 106, and the etch residue may have conductivity.

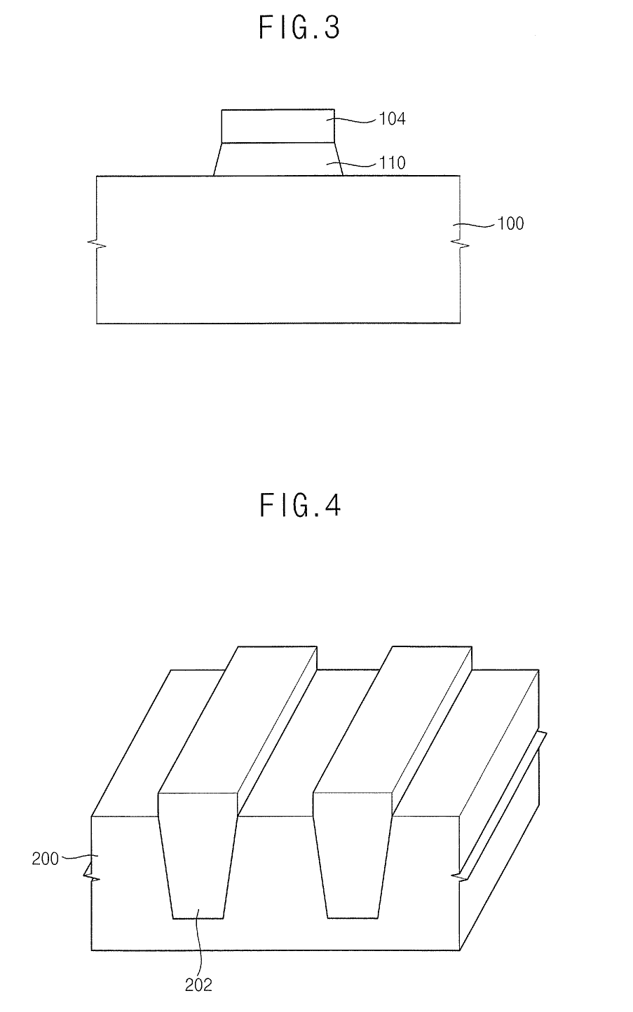

Referring to FIG. 3, a plasma etching process may be performed on the preliminary metal oxide layer pattern 106 to form a metal oxide layer pattern 110. The line width of the lower portion of the metal oxide layer pattern 119 may decrease.

In some embodiments, the plasma etching process may be performed in a chamber. In another embodiment, the plasma etching process may be performed in the same chamber where the preliminary metal oxide layer pattern 106 is formed.

A second source gas may be provided into the chamber. The second source gas may include a halogen-containing gas and/or an inert gas. The halogen-containing gas may include carbon tetrafluoride (CF₄), hydrogen bromide (HBr) or chlorine (Cl₂) and/or a combination thereof. In some embodiments, the halogen-containing gas may have an amount of about 0.1 to about 10.0% by weight based on the total weight of the second source gas. In another embodiment, the inert gas may include helium (He) gas, neon (Ne) gas, argon (Ar) gas, krypton (Kr) gas, xenon (Xe) gas, radon (Rn) gas, and/or a combination thereof. In some embodiments, the second source gas may further include hydrogen (H₂), nitrogen (N₂), oxygen (O₂) and/or a combination thereof.

The temperature of the chamber may be maintained at about 0 to about 300° C. and the pressure may be maintained of about 1 to about 100 mTorr. A bias power level of the chamber may be kept about 0 to about 500 W. Under these conditions, the preliminary metal oxide layer pattern 106 may be at least partially etched by the plasma process using the second source gas. In some embodiments, an anisotropic sputtering process using an inert gas may be performed to at least partially etch the preliminary metal oxide layer pattern 106 to form the metal oxide layer pattern 110. During the etching process, the lower portion of the preliminary metal oxide layer pattern 106 may be etched more than the upper portion because of the characteristics of the anisotropic sputtering process. Therefore, after the etching process of the preliminary metal oxide layer pattern 106 is performed, the lower portion of the formed metal oxide layer pattern 110 may be decreased.

In some embodiments, the second source gas including the halogen-containing gas may facilitate the etching process of the preliminary metal oxide layer pattern 106. The amount of the halogen-containing gas may be about 0.1 to about 10% by weight based on the total weight of the second source gas. When the amount of the halogen-containing gas exceeds 10.0% by weight based on the total weight of the second source gas, the preliminary metal oxide layer pattern 106 may be over etched.

After the etching process is performed, the line width of the lower portion of the metal oxide layer pattern 110 may decrease, and the etch residue 108 may be removed. Moreover, the possibility of contamination during transfer of the substrate 100 and the process time may be reduced by performing the plasma process in-situ.

FIGS. 4 to 9 present cross-sectional perspective views illustrating a method of forming a semiconductor device, for example a flash memory device, using the method of forming a metal oxide layer pattern 110 according to FIGS. 1 to 3.

As illustrated below, in some embodiments the method of forming a metal oxide layer according to FIGS. 1 to 3 may be used to form the blocking layer pattern.

Referring to FIG. 4, an active region may be defined by forming an isolation layer pattern 202 in the upper portion of a substrate 200. The substrate 200 may include a semiconductor substrate such as a silicon substrate or a germanium substrate, for example, a silicon-on-insulator (SOI) substrate or a germanium-on-insulator (GOI) substrate. In some embodiments, a silicon substrate is may be used.

The process of forming the isolation layer pattern 202 is illustrated below. A pad oxide layer (not shown in FIG. 4) may be formed on the substrate 200. A first mask (not shown in FIG. 4) may be formed on the pad oxide layer. In some embodiments, the pad oxide layer may include silicon oxide and may be formed by a thermal oxidation process and/or a CVD process. The first mask may include silicon nitride and be may be formed by a CVD process. In some embodiments, a pad oxide layer pattern (not shown in FIG. 4) and a trench (not shown in FIG. 4) may be formed by partially etching the pad oxide layer and the substrate 200 using the first mask as an etching mask. In some embodiments, the trench may be formed to extend along the first direction.

An isolation layer may be formed to at least partially fill the trench. An upper portion of the isolation layer may be polished to form the isolation layer pattern 202 to at least partially expose the top surface of the first mask. The isolation layer pattern 200 may extend along the first direction. In some embodiments, the active region may extend along the first direction and be defined by the isolation layer pattern 202. After the isolation layer pattern 202 is formed, the first mask and the pad oxide layer pattern may be removed.

In another embodiment, the pad oxide layer pattern and the first mask pattern may not be removed after the isolation layer pattern 202 is formed. The pad oxide layer pattern may serve as a tunnel insulation layer pattern and the first mask pattern may serve as a charge-trapping layer pattern. In some embodiments, the pad oxide layer pattern and the first mask pattern may be removed if they are damaged during the etching process.

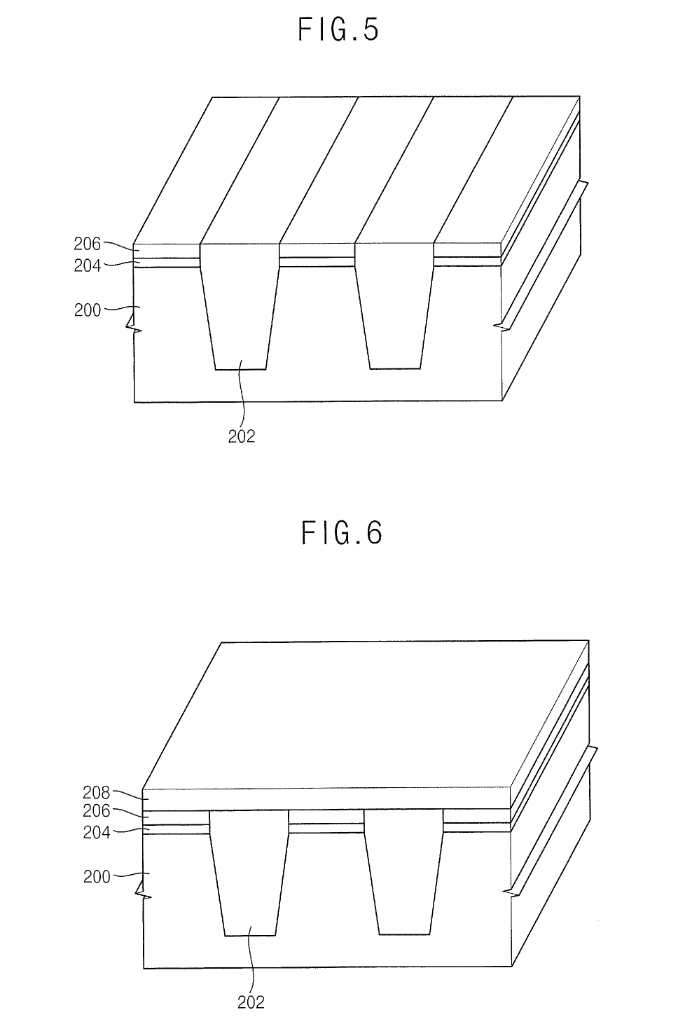

Referring to FIG. 5, the upper face of the substrate 200 may be exposed by the isolation layer pattern 202. A tunnel insulation layer pattern 204 and a charge-trapping layer pattern 206 may be sequentially stacked on the upper face of the substrate 200.

In some embodiments, the tunnel insulation layer pattern 204 may include an oxide such as silicon oxide, and the tunnel insulation layer pattern 204 may be formed by a thermal oxidation process and/or a CVD process.

During the thermal oxidation process, the upper face of the substrate 200 may be thermally oxidized to form a silicon oxide layer, which may serve as a tunnel insulation layer pattern 204. In some embodiments, the tunnel insulation layer pattern 204 may be formed without an etching process.

A charge-trapping layer may be formed on the tunnel insulation layer pattern 204 and the isolation layer pattern 202 to fill the space defined by the isolation layer pattern 202. Silicon nitride or silicon-rich oxide may be used to form a charge-trapping layer. In some embodiments, the charge-trapping layer may be formed by using a CVD process.

A portion of the charge-trapping layer may be polished to expose the top surface of the isolation pattern 202 to form the charge-trapping layer pattern 206.

The tunnel insulation layer pattern 204 and the charge-trapping layer pattern 206 may be formed on the active region. The tunnel insulation layer pattern 204 and the charge-trapping layer pattern 206 may form a bar shape extending along the first direction. Referring to FIG. 6, a blocking layer 208 may be formed on the isolation layer pattern 202 and the charge-trapping layer pattern 206. In some embodiments, the blocking layer pattern 208 may be formed using an oxide such as silicon oxide or metal oxide. The metal oxide may include aluminum oxide (Al₂O₃), hafnium oxide (HfO₂), zirconium oxide (ZrO₂), tantalum oxide (TaO₂), hafnium aluminate (HfAlO), zirconium silicate (ZrSiO), hafnium silicate (HfSiO), lanthanum aluminate (LaAlO), and/or a combination thereof. The blocking layer pattern may be formed by a CVD process and/or an ALD process. In another embodiment, the blocking layer 208 may be formed by a process which is substantially the same as that of the process of forming the metal oxide layer 102 in FIG. 1.

In some embodiments, the blocking layer pattern may include PZT (Pb(Zr, Ti )O₃), SBT (SrBi₂Ti₂O₉), BST(Ba(Sr, Ti)O₃), and/or a combination thereof.

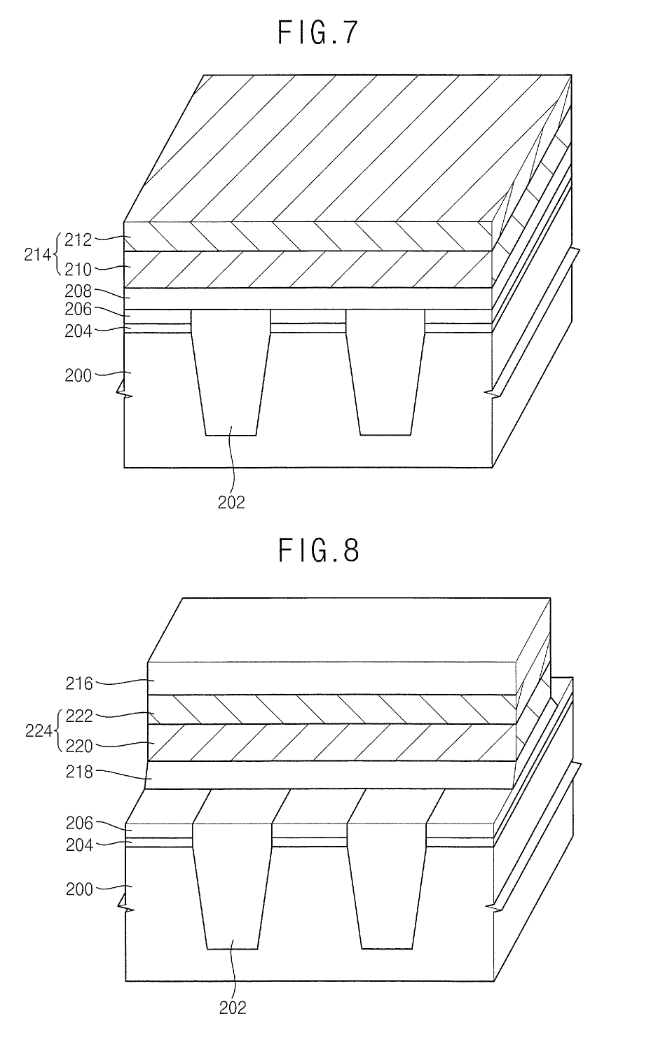

Referring to FIG. 7, a conductive layer 214 may be formed on the blocking layer 208. In some embodiments, the conductive layer 214 may be formed by using polysilicon doped with impurities, a metal, a metal silicide, a metal nitride, and/or a combination thereof. The conductive layer 214 may be formed by a CVD process, and/or a physical vapor deposition (PVD) process.

In some present embodiments, a tantalum nitride layer 210 and a tungsten layer 212 may be sequentially stacked to form the conductive layer 214.

Referring to FIG. 8, a second mask 216 may be formed on the conductive layer 214. The second mask 216 may be formed by using a nitride such as silicon nitride, and it may have a bar shape extending along a second direction which is substantially perpendicular to the first direction. The conductive layer 214 and the blocking layer 208 may be partially etched using the second mask 216 as an etching mask to form a conductive layer pattern 224 and a preliminary blocking layer pattern 218. In another embodiment, the conductive layer 214 and the blocking layer 208 may be etched by a plasma etching process. The plasma etching process may be referred to as the first plasma process.

In some embodiments, the first plasma process may be performed in a chamber. A first source gas including a halogen-containing gas and/or an inert gas may be introduced into the first chamber. In some embodiments, the halogen-containing gas may include carbon tetrafluoride (CF₄), hydrogen bromide (HBr) or chlorine (Cl₂), and/or a combination thereof. The amount of the halogen-containing gas may be at least about 10% by weight based on the total weight of the first source gas. In some embodiments, the inert gas may include nitrogen (N₂) gas, helium (He) gas, neon (Ne) gas, argon (Ar) gas, and/or a combination thereof.

The conductive layer 214 and the blocking layer 208 may be at least partially etched using the first source gas. During the etching process, the conductive layer 214 may be etched to form a conductive layer pattern 224 with a sidewall, which may be substantially perpendicular to the substrate 200. The blocking layer 208 may be etched to form a preliminary blocking layer pattern 218 using the second mask 216 and the conductive layer pattern 224 as an etching mask. The line width of sidewalls of the preliminary blocking layer pattern 218 may gradually increase in a vertically downward direction from the upper surface.

Etch residue from the formation of the conductive layer pattern 224 may remain on the sidewalls of the preliminary blocking layer pattern 218. The remaining etched portion may be referred to as etch residue. If the etch residue has conductivity, it may have an adverse impact on the reliability of the blocking layer pattern 218.

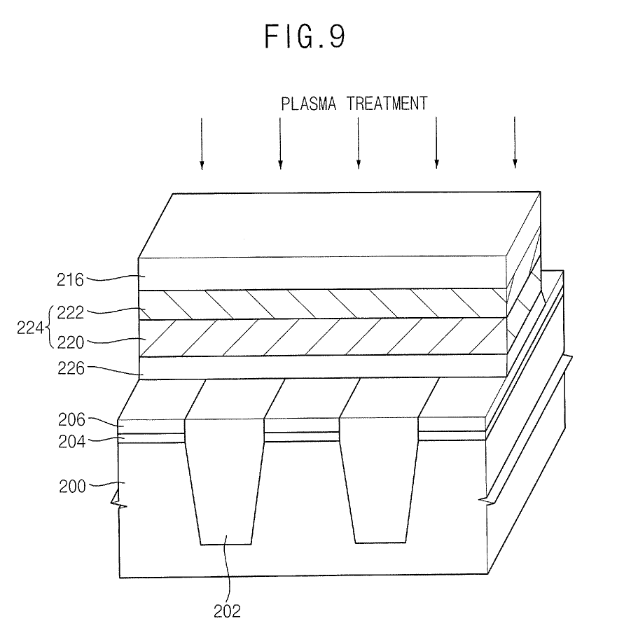

Referring to FIG. 9, a second plasma etching process may be performed on the preliminary blocking layer pattern 218 to form a blocking layer pattern 226. The line width of the lower portion of the blocking layer pattern 226 may be decreased. In some embodiments, the second plasma process may be performed in a second chamber. In another embodiment, the second plasma process may be performed in the same chamber where the first plasma process is performed.

A second source gas may be introduced into the second chamber. In some embodiments, the second source gas may include a halogen-containing gas and/or an inert gas. The halogen-containing gas may include carbon tetrafluoride (CF₄), hydrogen bromide (HBr) or chlorine (Cl₂), and/or a combination thereof. The amount of the halogen-containing gas may be about 0.1 to about 10.0% by weight based on the total weight of the second source gas. The inert gas may include helium (He) gas, neon (Ne) gas, argon (Ar) gas, krypton (Kr) gas, xenon (Xe) gas, radon (Rn) gas, and/or a combination thereof. The second source gas may further include hydrogen (H₂), nitrogen (N₂), oxygen (O₂) and/or a combination thereof.

In some embodiments, the temperature of the second chamber may be maintained at about 0 to about 300° C. under and the pressure of the second chamber may be maintained at about 1 to about 100 mTorr. A bias power level may be about 0 to about 500 W.

In another embodiment, at least a portion of the preliminary blocking layer pattern 218 may be etched using the second source gas to form the blocking layer pattern 226. During the etching process, the etch residue remaining on the sidewall of the preliminary blocking layer pattern 218 may be removed. The etching process may be substantially the same as the etching process illustrated in FIG. 1 to FIG. 3.

The conductive layer pattern 224 and the blocking layer pattern 226 may be formed on the tunnel insulation layer pattern 204 and the charge-trapping layer pattern 206. In some embodiments, the conductive layer pattern 224 and the blocking layer pattern 226 may extend along the first direction and in another embodiment, they may extend along the second direction which is substantially perpendicular to the first direction.

The line width of the lower portion of the blocking layer pattern 226 may be shorter than that of the preliminary blocking layer pattern 218, and thus, the semiconductor device including the blocking layer pattern 226 may have a higher degree of integration. In addition, the etch residue on the sidewall of the preliminary blocking layer pattern 218 may be removed to improve the reliability of the semiconductor device.

In some embodiments, the first and second plasma processes may be performed in-situ to reduce contaminations during the transfer and/or reduce processing time.

The blocking layer pattern 226, the conductive layer pattern 224 and/or the second mask pattern 216 may be used as etch masks for etching the charge-trapping layer pattern 206, and the etching process may result in an island shape. After the etching process is performed, the charge-trapping layer patterns 206 may have a plurality of patterns which may be isolated from each other. Consequently, electrons or holes stored in one charge-trapping layer patterns 206 may be prevented from moving to another charge-trapping layer pattern 206.

Impurities are may be implanted on a portion of the substrate 200 where the charge-trapping layer pattern 206 is formed. The implanted impurities may form a source/drain region. During the implantation process, the tunnel insulation layer pattern 204 may protect the substrate 200.

As a result, the floating trap-type flash memory device formed on the substrate 200 may include the tunnel insulation layer pattern 204, the charge-trapping layer pattern 206, the blocking layer pattern 226, the conductive layer pattern 224, and/or the source/drain region.

In some embodiments, the metal oxide layer prepared according to the method illustrated in FIGS. 1 to 3 may be used as a blocking layer pattern of non-volatile memory device. The blocking layer pattern may be formed by using a plasma etching process, which uses a source gas including a halogen-containing gas and/or an inert gas. After the etching process is performed, the line width of the blocking layer pattern may be reduced. During the etching process, the etch residue on the sidewall of the metal oxide layer may be removed, and the reliability of a semiconductor device may be improved.

In some embodiments, forming the preliminary blocking layer pattern, the first conductive layer pattern and the block layer pattern are performed in-situ.

In some embodiments, one or more conductive layers may be formed prior to forming the preliminary blocking layer pattern. In another embodiment, a second conductive layer may be formed prior to forming the preliminary blocking layer pattern. The second conductive layer may include platinum (Pt), iridium (Ir), palladium (Pd) ruthenium (Ru) and/or a combination thereof.

In some embodiments, during the manufacture a semiconductor device, etching the preliminary metal oxide layer pattern is performed by using a plasma etching process with a source gas comprising a halogen-containing gas, an inert gas and/or a combination thereof, and the amount of the halogen-containing gas being in a range from about 0.1 to about 10% by weight based on the total weight of the source gas.

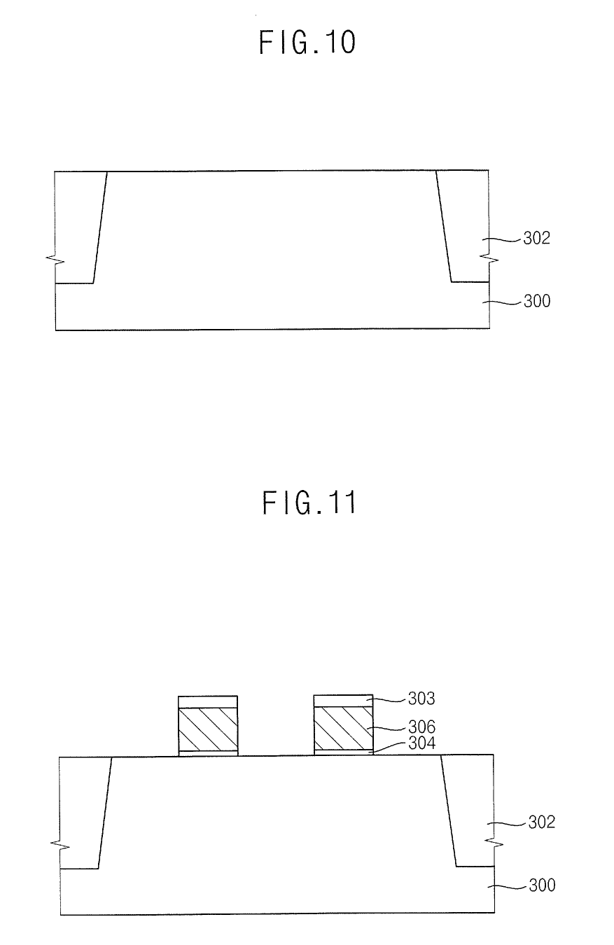

FIGS. 10 to 20 are present cross-sectional views illustrating a method of forming a ferroelectric memory device using the method of forming the metal oxide layer 102 in FIGS. 1 to 3.

Referring to FIG. 10, an active region is defined by forming an isolation layer 302 in the upper portion of a substrate 300. The substrate 300 may include a semiconductor substrate such as a silicon substrate or a germanium substrate such as a silicon-on-insulator (SOI) substrate or a germanium-on-insulator (GOI) substrate. The isolation layer 302 may be formed by a shallow trench isolation (STI) process. The process for forming the isolation layer 302 may be substantially the same as the process illustrated in FIG. 4.

Referring to FIG. 11, a gate insulation layer and a first conductive layer may be sequentially formed on the substrate 300. In some embodiments, the gate insulation layer may be formed using an oxide such as silicon oxide, and it may be formed by a thermal oxidation process and/or a CVD process.

In another embodiment, silicon doped with impurities, a metal, a metal silicide, a metal nitride, and/or a combination thereof may be used to form the first conductive layer. The first conductive layer may be formed by a CVD process and/or a PVD process.

The first mask 303 may be formed on the first conductive layer to at least partially expose the first conductive layer. The first mask 303 may include a nitride such as silicon nitride. When the first mask 303 is used as an etching mask, the first conductive layer and the gate insulation layer may be etched to form a gate structure comprising a first conductive pattern 306 and/or a gate-insulating pattern 304.

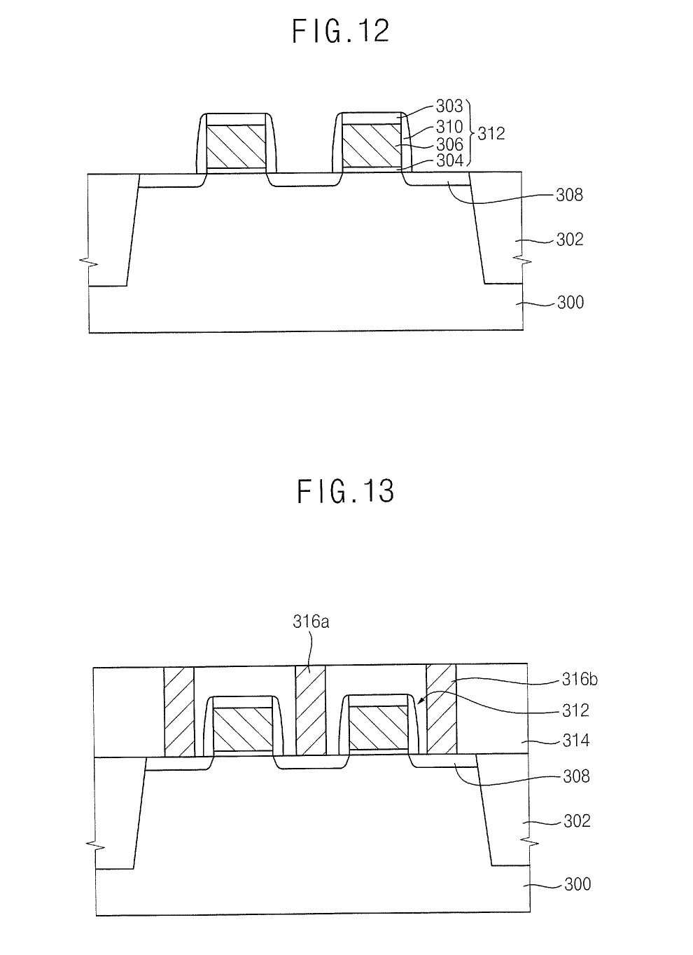

Referring to FIG. 12, a source/drain region 308 may be formed by implanting impurities on an exposed portion of the substrate exposed by the gate structure. In some embodiments, a spacer 310 may be formed on the sidewall of the gate structure. A nitride such as silicon nitride may be used to form the spacer 310.

In the source/drain region 308, a lightly doped drain (LDD) structure may be formed by implanting impurities on an exposed area of the substrate 300 by the spacer 310. A transistor 312 including the gate structure and/or the source/drain region 308 may be formed on the substrate 300.

Referring to FIG. 13, a first insulating interlayer may be formed on the substrate 300 to cover the transistor 312. The first insulating interlayer may be formed using an oxide with good filling characteristics. In some embodiments, the oxide may include undoped silicate glass (USG), O₃-tetraethyl orthosilicate undoped silicate glass (O₃-TEOS USG) or high-density plasma (HDP) oxide, and/or a combination thereof.

A first insulating interlayer pattern 314 may be formed to provide the first and second contact holes to at least partially expose the source/drain region 308. Subsequently, a second conductive layer may be provided to fill the first and the second contact holes. Subsequently, the upper portion of the second conductive layer may be polished to at least partially expose the first insulating interlayer pattern 314. Then, a first contact 316a and a second contact 316b may be formed and they pass through the first insulating interlayer pattern 314 to be electrically connected to the source/drain region 308.

In some embodiments, a bit line (not shown in FIG. 13) may be electrically connected to the source region of the source/drain region 308 through the first contact 316a, and a capacitor may be electrically connected to a drain region of the source/drain region 308 through the second contact 316b.

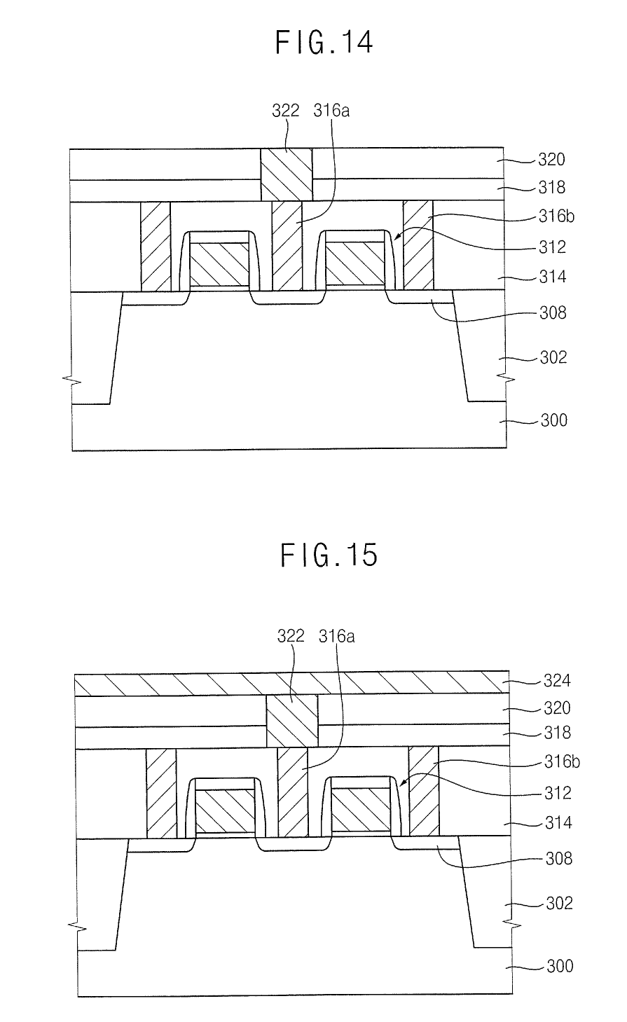

Referring to FIG. 14, a second insulating interlayer may be formed on the surface of the first insulating interlayer pattern 314, the first and second contacts 316a and 316b. A second insulating interlayer pattern 318 may be formed to at least partially expose the first contact 316a through an opening. Subsequently, the opening may be filled with a third conductive layer. Then, the third conductive layer may be polished to at least partially expose the second insulating interlayer pattern 318, and form a bit line.

In addition, a third insulating interlayer layer may be formed on the surface of the second insulating interlayer pattern 318 and the bit line. Then, a third insulating interlayer pattern 320 may be formed to expose the second contact 316b through a third contact hole. Subsequently, a fourth conductive layer pattern 320 may be formed to fill the third contact hole. At least a portion of the fourth conductive layer may be removed until a contact pad 322 is formed to at least partially expose the surface of the third insulating interlayer pattern 320.

Referring to FIG. 15, a lower electrode layer 324 for a capacitor may be formed on the contact pad 322 and the third insulating interlayer pattern 320. The lower electrode layer 324 may be formed using a metal, a metal nitride material, and/or a combination thereof. The lower electrode layer 324 may be formed by a CVD process, a sputtering process, a pulse laser deposition (PLD) process and/or an ALD process.

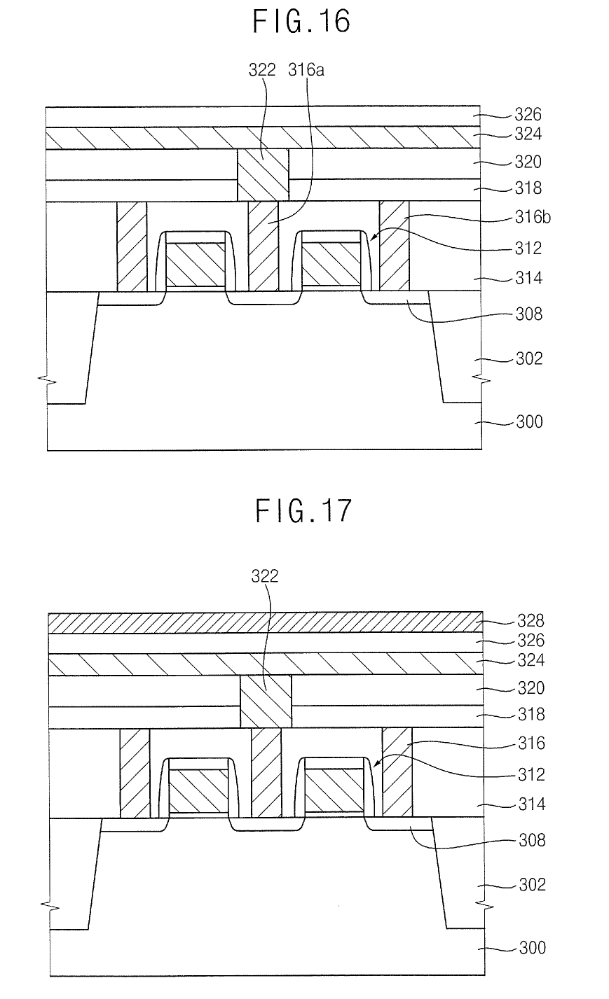

Referring to FIG. 16, a ferroelectric layer 326 may be formed on the lower electrode layer 324. In some embodiments, the ferroelectric layer 326 may be formed using a ferroelectric material such as PZT (Pb(Zr, Ti)O₃), SBT (SrBi₂Ti₂O₉), BST (Ba(Sr, Ti)O₃), bismuth lanthanum titanate (Bi(La, Ti)O₃; BLT), lead lanthanum zirconium titanate (Pb(La, Zr)TiO₃; PLZT), and/or a combination thereof. In another embodiment, the ferroelectric layer 326 may be formed using a ferroelectric material such as PZT, SBT, BST, BLT or PLZT, which are may be doped with impurities such as calcium (Ca), lanthanum (La), manganese (Mn), and/or bismuth (Bi).

In still another embodiment, the ferroelectric layer 326 may be formed using a metal oxide such as titanium oxide (TiOₓ), tantalum oxide (TaOₓ), aluminum oxide (AlOₓ), zinc oxide (ZnOₓ), hafnium oxide (HfOₓ), and/or a combination thereof.

The ferroelectric layer 326 may be formed by an MOCVD process, a sol-gel process, a liquid phase epitaxy (LPE) process and/or an ALD process.

Referring to FIG. 17, an upper electrode 328 may be formed on the ferroelectric layer 326. In some embodiments, the upper electrode 328 may be formed using a metal such as iridium (Ir), platinum (Pt), ruthenium (Ru), palladium (Pd), gold (Au), and/or a combination thereof. In another embodiment, the upper electrode 328 may be formed using a metal alloy such as platinum manganese (PtMn) or ruthenium iridium (RuIr). In still another embodiment, the upper electrode 328 may be formed using a metal oxide such as iridium oxide (IrOₓ), strontium ruthenium oxide (SrRuO₃; SRO), strontium titanium oxide (SrTiO₃; STO), lanthanum nickel oxide (LaNiO₃; LNO), calcium ruthenium oxide (CaRuO₃; CRO), and/or a combination thereof. The upper electrode 328 may be formed by a PVD process, a CVD process, an ALD process and/or a PLD process.

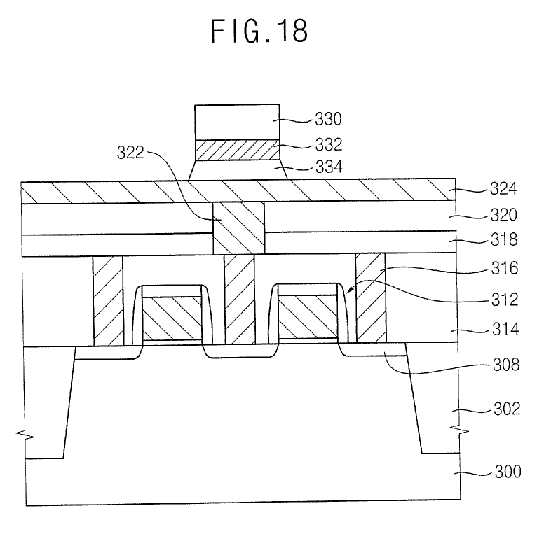

Referring to FIG. 18, a second mask pattern 330 may be formed on the upper electrode 328. In some embodiments, the second mask pattern 330 may include a nitride such as silicon nitride. In further embodiments, the second mask pattern 330 may be used as an etching mask, and then the upper electrode layer 328 and the ferroelectric layer 326 may be partially etched to form an upper electrode 332 and a preliminary ferroelectric layer pattern 334.

The upper electrode layer 328 and the ferroelectric layer 326 may be partially etched by a plasma etching process, which may be referred to as a first plasma etching process.

The first plasma etching process may be performed in the first chamber. A first source gas including a halogen-containing gas and/or an inert gas may be introduced to the chamber. In some embodiments, the halogen-containing gas may include carbon tetrafluoride (CF₄), hydrogen bromide (HBr) or chlorine (Cl₂), and/or a combination thereof. The amount of the halogen-containing gas may be more than about 10% by weight based on the total weight of the first source gas. In another embodiment, the inert gas may include nitrogen (N₂) gas, helium (He) gas, neon (Ne) gas, argon (Ar) gas, and/or a combination thereof.

The upper electrode layer 328 and the ferroelectric layer 326 may be etched using the first source gas in the first chamber. The first source gas may be used to perform the first plasma process to form the upper electrode 332, a vertical profile of which may be substantially perpendicular to the substrate 300. The ferroelectric layer 326 may be etched to form a preliminary ferroelectric layer pattern 334 and the second mask 330 and the upper electrode 332 are used as the etching mask. A line width of the preliminary ferroelectric layer pattern 326 may gradually increase in a vertically downward direction from the upper face of the preliminary ferroelectric layer pattern 326, which may result in an inclined sidewall with respect to the substrate 300.

When the ferroelectric layer 326 is etched to form the upper electrode pattern 332, a portion of the ferroelectric layer 326 may remain on the sidewall of the preliminary ferroelectric layer pattern 334, which may be referred to as etch residue. The etch residue may be a polymer with conductivity and should be reduced.

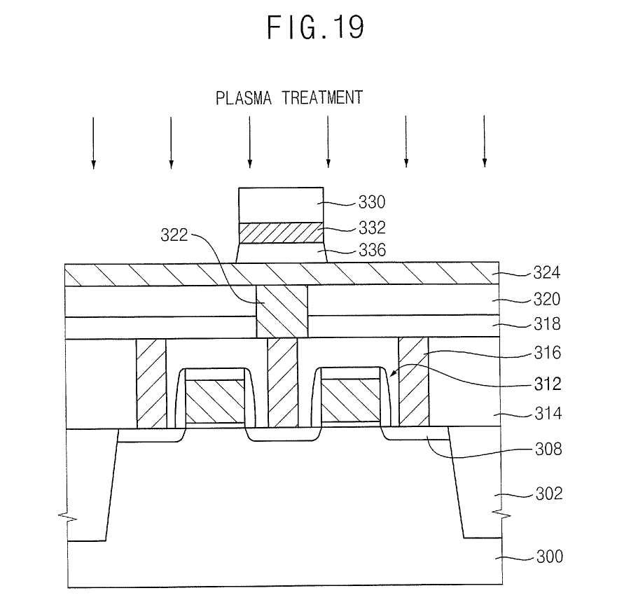

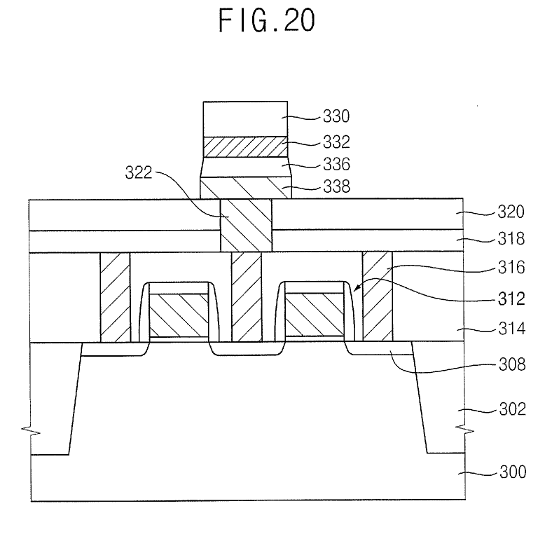

Referring to FIG. 19, a second plasma etching process may be performed on the preliminary ferroelectric layer pattern 334 to form a ferroelectric layer pattern 336. The line width of a lower portion of the ferroelectric layer pattern 336 may be decreased by the second plasma etching process. The second plasma etching process may be performed in a second chamber. In some embodiments, the second plasma process may be performed in-situ in the first chamber where the first plasma process is performed.

A second source gas may be provided into the chamber. The second source gas may include a halogen-containing gas and/or an inert gas. In some embodiments, the halogen-containing gas may include carbon tetrafluoride (CF₄), hydrogen bromide (HBr) or chlorine (Cl₂), and/or a combination thereof. In another embodiment, the amount of halogen-containing gas may be about 0.1 to about 10.0% by weight based on the total weight of the second source gas. The inert gas may include helium (He) gas, neon (Ne) gas, argon (Ar) gas, krypton (Kr) gas, xenon (Xe) gas, radon (Rn) gas, and/or a combination thereof. The second source gas may further include hydrogen (H₂), nitrogen (N₂), oxygen (O₂) and/or a combination thereof.

The temperature of the second chamber may be maintained at about 0° C. to about 300° C. and the pressure may be maintained about 1 to about 100 mTorr. A bias power level of the second chamber may be kept in the range of about 0 W to about 500 W.

At least a portion of the ferroelectric layer pattern 336 may be etched to form the ferroelectric layer pattern 336. The line width of a lower portion of the ferroelectric layer pattern 336 may be shorter than that of the preliminary ferroelectric layer pattern 334 at least because the etch residue remaining on a sidewall of the preliminary ferroelectric layer pattern 334 may be removed. The etching process may be substantially the same as the process described in FIG. 3.

Referring to FIG. 20, the second mask pattern 330, the upper electrode 332 and the ferroelectric layer pattern 336 may be used as etching masks to form the lower electrode layer 324. Therefore, the capacitor of the ferroelectric memory device may include the lower electrode 338, the ferroelectric layer pattern 336 and the upper electrode 332.

In some embodiments, a metal oxide layer pattern with a desirable vertical profile may be formed by a plasma etching process using a source gas including a halogen-containing gas. The amount of the halogen-containing gas may be about 0.1 to about 10% by weight based on the total weight of a source gas. In addition, etch residue on a sidewall of the metal oxide layer pattern may be removed to improve the reliability of a semiconductor device.

In some embodiments, a metal oxide layer pattern may serve as a dielectric layer, the ferroelectric dielectric layer pattern may be formed by using a plasma etching process with a source gas including a halogen-containing gas. The etching process reduces the line width of the lower portion of the ferroelectric dielectric layer pattern. During the etching process, the etch residue on the sidewall of the metal oxide layer pattern may be removed and the reliability of a semiconductor device may be improved.

In some embodiments, a metal oxide layer pattern may be used as a dielectric layer of a ferroelectric memory device. The lower line width of a ferroelectric layer pattern may be reduced by a plasma etching process using a gas including halogen atoms. During the etching process, the etch residue on a sidewall of the ferroelectric layer pattern may be reduced, and the reliability of the ferroelectric memory device may be enhanced.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of forming a metal oxide layer pattern on a substrate, comprising:
providing a metal oxide layer on a substrate;
etching the metal oxide layer to provide a preliminary metal oxide layer pattern, wherein the line width of the preliminary metal oxide layer pattern gradually increases in a vertically downward direction;
etching the preliminary metal oxide layer pattern to form a metal oxide layer pattern in a manner so as to decrease the line width of a lower portion of the preliminary metal oxide layer pattern.

2. The method of claim 1, wherein etching the preliminary metal oxide layer pattern is performed by using a plasma etching process with a source gas.

3. The method of claim 2, wherein the source gas comprising a halogen-containing gas, an inert gas and/or a combination thereof.

4. The method of claim 3, wherein the amount of the halogen-containing gas is in a range from about 0.1 to about 10% by weight based on the total weight of the source gas.

5. The method of claim 3, wherein the halogen-containing gas comprises carbon tetrafluoride (CF₄), hydrogen bromide (HBr), chlorine (Cl₂) and/or a combination thereof.

6. The method of claim 3, wherein the inert gas comprises helium gas (He), neon gas (Ne), argon gas (Ar), krypton gas (Kr), xenon gas (Xe), radon gas (Rn), and/or a combination thereof.

7. The method of claim 3, wherein the source gas further comprises hydrogen (H₂), nitrogen (N₂), oxygen (O₂), and/or a combination thereof.

8. The method of claim 1, wherein the metal oxide layer comprises one or more materials with a high dielectric constant and/or one or more ferroelectric materials.

9. The method of claim 8, wherein the material with the high dielectric constant comprises aluminum oxide (Al₂O₃), hafnium oxide (HfO₂), zirconium oxide (ZrO₂), tantalum oxide (TaO₂), hafnium aluminate (HfAlO), zirconium silicate (ZrSiO), hafnium silicate (HfSiO), lanthanum aluminate (LaAlO), and/or a combination thereof.

10. The method of claim 8, wherein the ferroelectric material comprises lead zirconate titanate (Pb(Zr, Ti)O₃; PZT), strontium bismuth titanate (SrBi₂Ti₂O₉; SBT), barium strontium titanate (Ba(Sr, Ti)O₃; BST) and/or a combination thereof.

11. The method of claim 1, wherein etching the preliminary metal oxide layer pattern is performed at a temperature in a range of about 0° C. to about 300° C., under a pressure in a range of about 1 to about 100 mTorr, and at a bias power level in a range of about 0 to about 500 W.

12. A method of manufacturing a semiconductor device, comprising:
forming a metal oxide layer and a first conductive layer on a substrate;
etching the metal oxide layer to provide a preliminary metal oxide layer pattern, wherein the line width of the preliminary metal oxide layer pattern gradually increases in a vertically downward direction;
etching the first conductive layer to provide a first conductive layer pattern; and
etching the preliminary metal oxide layer pattern to provide a metal oxide layer pattern in a manner so as to decrease the line width of a lower portion of the preliminary metal oxide layer pattern.

13. The method of claim 12, further comprising forming a tunnel insulation layer pattern and a charge-trapping layer pattern on the substrate prior to forming the metal oxide layer.

14. The method of claim 12, wherein the first conductive layer comprises polysilicon doped with impurities, a metal, a metal silicide, a metal nitride, and/or a combination thereof.

15. The method of claim 12, wherein the metal oxide layer comprises PZT (Pb(Zr, Ti )O₃), SBT (SrBi₂Ti₂O₉), BST(Ba(Sr, Ti)O₃), and/or a combination thereof.

16. The method of claim 12, further comprising forming a second conductive layer prior to etching the metal oxide layer to provide a preliminary metal oxide layer pattern.

17. The method of claim 12, wherein the second conductive layer comprises platinum (Pt), iridium (Ir), palladium (Pd), ruthenium (Ru) and/or a combination thereof.

18. The method of claim 12, wherein the metal oxide layer pattern serves as a blocking layer pattern or a dielectric pattern.

19. The method of claim 12, wherein etching the preliminary metal oxide layer pattern is performed by using a plasma etching process with a source gas comprising a halogen-containing gas, an inert gas and/or a combination thereof, and the amount of the halogen-containing gas being in a range from about 0.1 to about 10% by weight based on the total weight of the source gas.

20. The method of claim 12, wherein etching the metal oxide layer to provide a preliminary metal oxide layer pattern, etching the first conductive layer to provide a first conductive layer pattern and etching the preliminary metal oxide layer pattern to provide a metal oxide layer pattern are performed in-situ.
